(19) United States
(12) Patent Application Publication
(10) Pub. No.: US 2003/0084999 A1
(43) Pub. Date: May 8, 2003

(54) Apparatus and method for mitigating chamber resonances in plasma processing

(75) Inventors: Richard Parsons, Phoenix, AZ (US); Steven T. Fink, Mesa, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 10/287,530

(22) Filed: Nov. 5, 2002

Related U.S. Application Data
(60) Provisional application No. 60/330,961, filed on Nov. 5, 2001.

(51) Int. Cl. H01L 21/306; C23C 16/00

(52) U.S. Cl. 156/345.43; 118/723 R; 118/723 I; 118/723 E; 156/345.46; 156/345.47; 156/345.48; 156/345.49

(57) ABSTRACT

A plasma processing system that includes a chamber enclosing a plasma region. The system has a plasma source including a power source coupled to an electrode provided within the chamber to deliver RF power into the plasma region. The RF power forms an RF electromagnetic field that interacts with a gas in the plasma region to create a plasma. In one embodiment, an absorbing surface including an RF absorber is provided within the plasma region, and a protective layer is provided on the absorber to seal the absorber from plasma within the plasma region. Alternately, a non-reflecting surface is provided within the plasma region. The non-reflecting surface comprises a layer of dielectric material and acts to minimize reflection of RF power at a design frequency. The non-reflecting surface further includes a thickness equivalent to the quarter wavelength of a wave propagating in the dielectric layer at the design frequency.

### CROSS-REFERENCE TO RELATED APPLICATIONS

This application is related to and claims priority to U.S. provisional serial No. 60/330,961, filed on Nov. 5, 2001, the entire contents of which are herein incorporated by reference.

### BACKGROUND OF THE INVENTION

1. Field of the Invention

The present invention relates to plasma processing systems, and particularly to the delivery of RF power to initiate and sustain a plasma in such systems.

2. Discussion of the Background

In the semiconductor integrated circuit (IC) fabrication industry, plasma processing devices, such as capacitively coupled plasma (CCP) sources, are widely used for dry etching and plasma enhanced chemical deposition. Dry etching is a process for removing a layer of material from a wafer surface. This removal process is a result of combined mechanical and chemical effects associated with the interaction between energetic plasma ions and chemical reactants, and the wafer surface. In plasma enhanced chemical deposition, a layer of a material is deposited on the wafer surface. This material is introduced into the plasma either by sputtering a target comprising the material (physical vapor deposition, PVD) or by supplying gas(es) containing elements of the deposition material from which the deposition material is produced by a chemical reaction (chemical vapor deposition, CVD). Furthermore, the material can be ionized by the plasma and can then be attracted to the wafer by an electric field (such as ionized physical vapor deposition, IPVD).

The trend in the semiconductor fabrication industry has been toward integrated circuits having ever smaller elemental features. As a result, etch and deposition rate uniformity over the wafer surface has become more important, particularly when a layer is being etched or deposited according to a pattern. At the same time, recent developments in plasma source technology have led to the increased use of very high frequency RF excitation, e.g. from 60 to 300 MHz, and possibly even higher, to initiate and sustain the plasma.

The use of these very high excitation frequencies provides a benefit in the form of increased power coupling to the plasma, and thus excitation efficiency, that is likely caused by an increase of plasma electron temperature. However, an increase in the excitation frequency leads to a decrease in the intrinsic wavelength of the coupled electromagnetic wave and, for harmonics of the excitation frequency comprising appreciable power, the respective wavelength can become of order the diameter of the processing chamber. Therefore, operating at elevated excitation frequencies and maintaining the requirements for etch and deposition rate uniformity levels at these very high excitation frequencies in the presence of strong harmonic amplitudes, particularly those harmonic frequencies coinciding with natural frequencies of the reactor RF system, can be a formidable challenge.

### SUMMARY OF THE INVENTION

Accordingly, a method and apparatus are provided by the present invention to reduce chamber resonances in a plasma processing chamber in order to increase the uniformity of the plasma process being performed within the chamber.

The present invention advantageously provides a plasma processing system that includes a chamber enclosing a plasma region. The system further includes an RF plasma source including an RF power source coupled to the chamber to deliver RF power into the plasma region. The RF power forms an RF electromagnetic field that interacts with a gas in the plasma region to create a plasma. An RF absorbing surface comprising an RF absorber is provided within the plasma region, and a protective layer is provided on the RF absorber to seal the RF absorber from plasma within the plasma region.

The present invention further advantageously provides a method for mitigating chamber resonances in a plasma chamber. The method includes providing an RF absorber within the chamber enclosing a plasma region, and sealing the RF absorber from the plasma region using a protective layer on the RF absorber. The method further provides creating plasma by delivering RF power from an RF power source to the plasma region within the chamber, where the RF power forms an RF electromagnetic field that interacts with a gas in the plasma region.

The present invention further advantageously provides a plasma processing system that includes a chamber enclosing a plasma region. The system further includes an RF plasma source including an RF power source coupled to an electrode provided within the chamber to deliver RF power into the plasma region. The RF power forms an RF electromagnetic field that interacts with a gas in the plasma region to create a plasma. A non-reflecting surface is provided within the plasma region, the non-reflecting surface comprises a layer of dielectric material and acts to minimize reflection of RF power at a design frequency. The non-reflecting surface further comprises a thickness equivalent to the quarter wavelength of a wave propagating in the dielectric layer at the design frequency.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1A is a schematic representation of a plasma processing system according to an embodiment of the present invention;

FIG. 1B is a schematic representation of a plasma processing system according to an alternate embodiment of the present invention;

FIG. 2 is a schematic representation of a plasma processing system according to an alternate embodiment of the present invention;

FIG. 3 is a partial cross-section view of a plasma processing system according to another embodiment of the present invention;

FIG. 4 is a graph depicting various resonances present within an exemplary plasma processing chamber; and

FIG. 5 is a schematic representation of a plasma processing system according to another embodiment of the present invention.

### DETAILED DESCRIPTION OF THE PREFERRED EMBODIMENTS

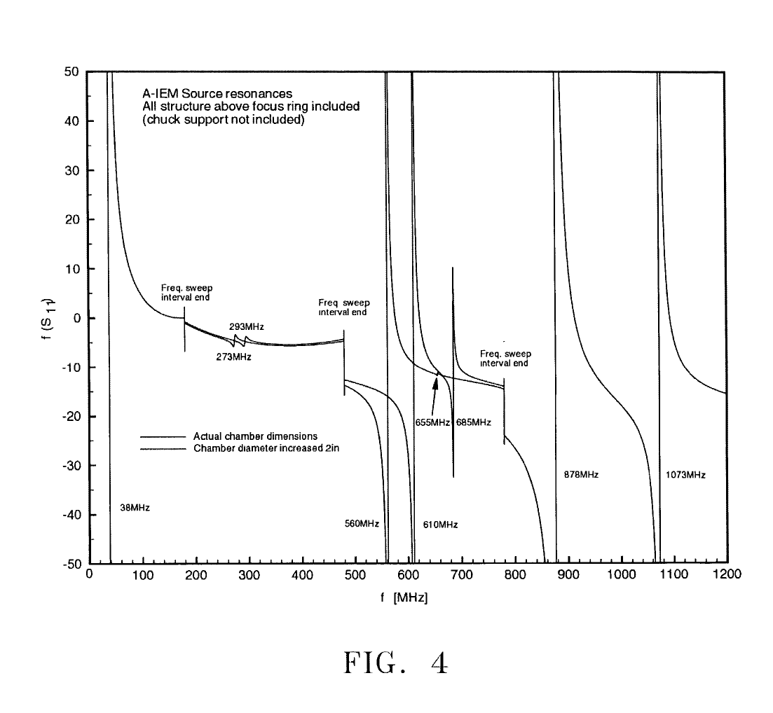

Plasma processing systems that utilize RF power to initiate and sustain a plasma typically generate within the plasma chamber harmonics of frequencies used to drive the excitation of the plasma. It is understood that this transfer of power to harmonics of the excitation frequency occurs through current rectification in the plasma sheath. Plasma processing machines used in the fabrication of integrated circuits have a wide variety of configurations and geometries. The physical configuration and size of the process chamber can exhibit resonances at specific frequencies arising from the formation of standing waves, which can further coincide with existing harmonic frequencies produced in the plasma, as is exemplified in FIG. 4. For example, FIG. 4 demonstrates the existence of chamber resonances from a frequency sweep. As shown in FIG. 4, a chamber resonance occurs substantially near 600 MHz, which is equal to the tenth (10^{th}) harmonic of the excitation frequency when the excitation frequency is 60 MHz. The existence of propagating electromagnetic waves at 600 MHz and the potential for the occurrence of a chamber resonance at substantially near this frequency can adversely affect the uniformity of the plasma process. As a process chamber is changed in configuration and size, the resonance frequencies are shifted in the frequency spectrum. Prediction of these anomalies is often difficult due to the complexity of the chamber and the plasma and their subsequent interaction at RF frequencies.

The present invention provides a method and apparatus for at least partially removing resonances that can, for example, occur at harmonic frequencies within the plasma chamber, thus improving process uniformity within the plasma chamber regardless of the configuration and geometry of the plasma processing system. The present invention generally utilizes an RF absorber material within the plasma chamber to mitigate the excitation of chamber resonances. The RF absorber material is generally sealed from the plasma processing environment using, for example, ceramic or quartz in order to prevent the deterioration of the RF absorber and to prevent contamination of the plasma processing environment. The RF absorber material is mounted in the process chamber at various desired locations in order to ensure that the RF frequencies generated in the chamber would in effect see a chamber of “infinite” size. If the chamber was “infinite,” then the occurrence of chamber resonances could be avoided, and thus uniformity can be improved.

The present invention advantageously utilizes the placement of an absorbing surface in the chamber to selectively absorb RF frequencies to mitigate the formation of chamber resonances and improve the uniformity of the process. The present invention can be configured in many different embodiments. For example, an RF absorbing surface comprising an RF absorbing material can include most of the interior of a process chamber or include only selected areas. The surface can include other parts located in or partially located in the process chamber. The absorber material should be sealed from the process chamber using a layer of ceramic and/or quartz that separates the absorber from the environment within the process chamber in order to ensure no particle generation or contamination of the process. For example, the sealing material can be sealed to the chamber or another piece of ceramic to completely encase the absorber material. The RF energy passes through the ceramic structure and is dissipated at the absorbing surface within the absorber material.

A plasma processing system of the type to which this invention is applied includes a chamber which encloses a plasma region filled with a suitable ionizable gas, such as argon, and into which RF electromagnetic energy is coupled. The energy interacts with the gas to initiate and sustain a plasma.

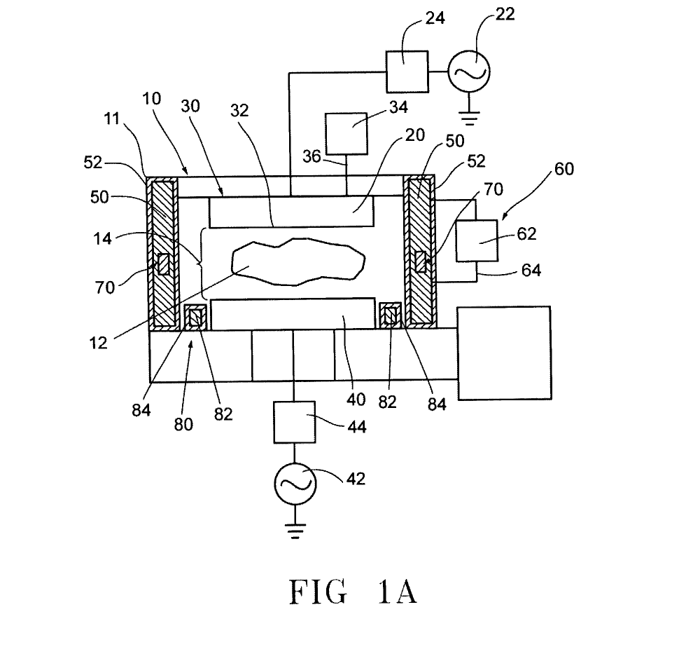

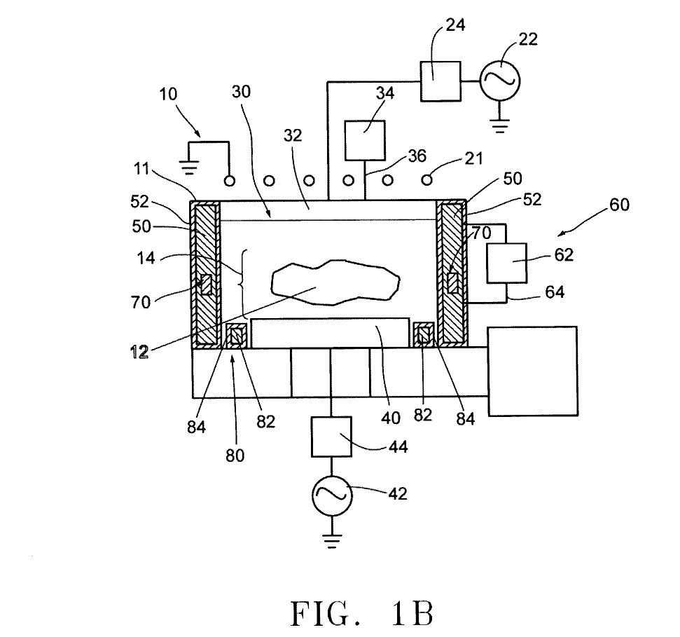

FIG. 1A depicts a schematic representation of a plasma processing system according to an embodiment of the present invention. The system includes a plasma processing chamber 10 that encloses a plasma region 14 (generally defined as the region between upper electrode 20 and chuck assembly 40) in which a plasma 12 is initiated and maintained. The plasma chamber 10 includes an upper electrode 20 connected to a plasma excitation RF source 22 that supplies RF power and a match network 24. The RF power source 22 is coupled to the upper electrode 20 to deliver RF power into the plasma region 14 where the RF power forms an RF electromagnetic field that interacts with a gas supplied from a gas injection assembly 30 to the plasma region 14 in order to create a plasma 12.

The upper electrode 20 is located at the top of a plasma chamber 10. The plasma processing system has a gas injection assembly 30 including a shower-head injection system 32 incorporated within the upper electrode 20, a gas supply system 34, and a conduit 36 that connects the gas supply system 34 to the shower-head injection system 32. The upper electrode 20 is of the shower-head type, provided with a plurality of passages (not shown) for delivery of process gas to the plasma region 14 from a plenum. The plenum is supplied with process gas by a gas feed line 36 connected to a process gas source within the gas supply system 34.

A wafer chuck 40 is located at the bottom of the plasma region 14 and is connected to a wafer chuck RF source 42 via a second match network 44. Electrodes 20 and 40 form a capacitively-coupled RF plasma source used for performing an etch or deposition operation on a wafer mounted on chuck 40. Source 42 acts primarily to apply a RF bias and, in turn, impose a DC self-bias on wafer chuck 40, which self-bias acts to attract ions to the surface of the wafer mounted on chuck 40.

The plasma processing system of the present invention further includes an RF absorber 50 provided within the plasma chamber 10. In the embodiment depicted in FIG. 1A, the RF absorber 50 is generally cylindrical in shape and is provided along an interior surface of a cylindrical sidewall 11 of the chamber 10. Preferred embodiments of the invention employ a special class of dielectric materials, or so-called “RF absorbers.” Examples of RF absorber materials are members of the ECCOSORB® CR castable resin family, marketed by Emerson & Cuming Microwave Products, Inc. of 869 Washington St., Ste. 1, Canton, Mass. 02021. These absorber materials are iron powder loaded epoxy resins. The family includes over a dozen types of absorber resins, of varying levels of RF attenuation. One example of an ECCOSORB® material that could be used in the present invention is a castable absorber sold under the product designation CR-117.

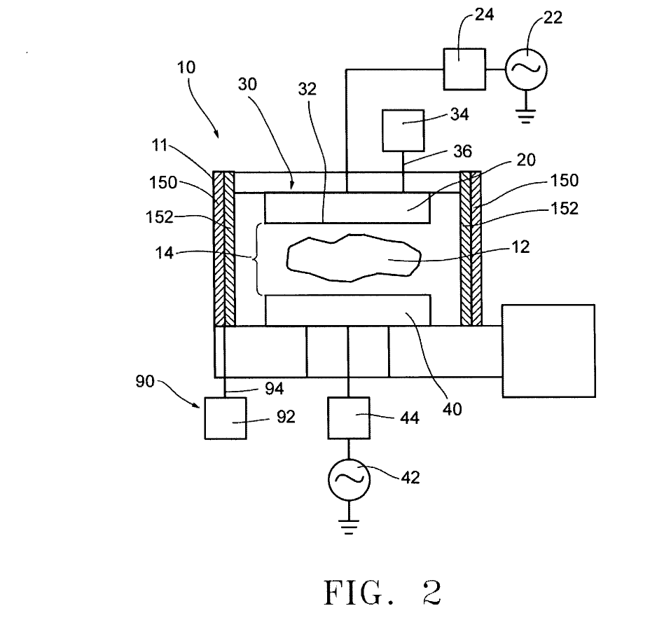

The system further includes a protective layer 52 provided on the RF absorber 50 to seal the RF absorber 50 from plasma within the plasma region 14. In the embodiment depicted in FIG. 1A, the RF absorber 50 is embedded, captivated, encased or encapsulated within the protective layer 52, however, numerous other configurations are possible. For example, the embodiment depicted in FIG. 2 includes a protective layer 152 that seals an RF absorber layer 150 to an interior surface of the side wall 11 of the chamber 10. The protective layer 152 is a one-piece chamber liner that is sealed to an interior surface of the chamber 10, such that the RF absorber 150 is located between the protective layer 152 and the interior surface of the chamber 10. The protective layer can be made of ceramic, quartz, or any material that provides for the transmission of RF power therethrough while sealing the RF absorber from the plasma processing environment. Periodically the protective layer over the RF absorber will need to be cleaned.

The RF absorber 50 depicted in FIG. 1A generally extends around the plasma region 14 to partially or completely remove the chamber resonance problems from plasma region 14. The RF absorber 50 has a ring-shaped configuration extending downward from an injection assembly 30 of the plasma chamber 10 and around a chuck assembly 40 of the plasma chamber 10. The RF absorber 50 of FIG. 1A is generally cylindrically shaped, however various other shapes and configurations can be used. For example, the RF absorber could be formed of a hollow conical shape with an open end extending downward around the plasma region 14. Alternatively, the RF absorber could be formed of a hollow frustoconical shape that extends around the plasma region 14. Further alternatively, the RF absorber can be provided in the plasma chamber 10 in removable or permanently attached sections that are either planar in shape to form various polygon configurations around the plasma region 14, or curved in shape to form cylindrical shapes. The sections of RF absorbers can be encased within a protective layer, and mounted directly to the walls of the chamber 10 or can be mounted by receiving the sections within brackets mounted to the chamber 10. RF absorbers can be positioned throughout the chamber 10 in order to provide the entire chamber with an “infinite” size with regard to the RF frequencies used within the chamber 10. The optimum configuration of RF absorbers for any given chamber size and configuration can be obtained by experimentation.

As the RF absorber 50 absorbs RF energy, the temperature of the RF absorber 50 will increase. Accordingly, in order to remove the excess heat from the RF absorber 50, a cooling system 60 is coupled to the RF absorber 50 and configured to extract heat from the RF absorber 50. The cooling system 60 is configured as a fluid cooling system including a heat exchange/pumping unit 62 and a fluid conduit 64 that extends within the RF absorber 50 to act as a heat exchanger that extracts heat from the RF absorber 50. Alternatively, the RF absorber 50 can be placed in a bath of coolant in order to extract heat from the RF absorber 50. Alternatively, the RF absorber is in thermal contact with a cooled chamber wall.

The plasma processing system can comprise permanent magnets that can be used to make the plasma more uniform. For example, the permanent magnets can be added to the RF absorber 50 or a focus ring assembly 80 (described below). In the embodiment depicted in FIG. 1A, a permanent magnet 70 is provided in conjunction with the RF absorber 50. The magnets can be added to RF absorbers with fluid cooling system.

The plasma processing system can further include a focus ring assembly 80 having an RF absorber 82 with a protective layer 84 provided therein. The focus ring assembly 80 typically encircles the chuck assembly 40 of the process chamber 10. The presence of the focus ring assembly 80 allows the equipotential field lines to be disposed substantially uniformly over an entire surface of a substrate provided on the chuck assembly 40. The presence of the RF absorber 82 in the focus ring assembly 80 will aid in the reduction or elimination of chamber resonances within the chamber 10 by reducing the reflection of the RF frequency signal off the structure of the focus ring assembly 80.

FIG. 1B presents an alternate embodiment of the present invention comprising similar elements as those described in reference to FIG. 1A except that upper electrode 20 is replaced with inductive coil antenna 21. Inductive coil antenna 21 can be coupled to RF source 22 through match network 24 at one end and coupled to ground at an opposite end. Furthermore, gas injection assembly 30 can be fabricated within a dielectric window in order to permit coupling of RF power between inductive coil antenna 21 and plasma 12.

FIG. 2 depicts a second embodiment that includes a protective layer 152 that seals an RF absorber layer 150 to an interior surface of the side wall 11 of the chamber 10. The second embodiment includes a motive mechanism 90 coupled to and configured to adjust a position of the RF absorber 150 and protective layer 152 within the chamber 10. The motive mechanism 90 including a drive device 92 and a linkage 94 connecting the drive device 92 to the RF absorber 150 and protective layer 152. The drive device 92 can be, for example, a linear actuator such as a hydraulic or pneumatic drive, an electric motor, a solenoid, etc.

The motive mechanism 90 can be utilized to adjust a position of the RF absorber 150 (and the protective layer 152 ) within the plasma chamber 10 in order to control the reflecting and absorbing characteristics of the chamber enclosure and, hence, the interaction of RF energy with plasma in the plasma region 14 and the plasma chamber 10. For example, the motive mechanism 90 can be used to control the process characteristics by changing the position of the RF absorber 150 to a position such that the RF absorber 150 does not completely encircle the plasma region 14, thereby changing a level of absorption of RF power within the plasma region 14. An example of a situation in which such a result would be beneficial is when it is beneficial to control the etch rate within the plasma region. The etch rate within the plasma region 14 can be controlled by adjusting an absorption rate of the RF absorber 150. More specifically, as absorption by the RF absorber increases, the etch rate drops. The etch rate can be controlled by adjusting a position of the RF absorber 150 with respect to the plasma 12 within the plasma region 14. The process of adjusting the etch rate can be beneficial, for example, as a method of controlling an etch stop within the plasma region by increasing the absorption rate of the RF absorber, thereby decreasing the etch rate at etch stop.

An alternative method of controlling the formation of chamber resonances present within the plasma region 14 or the plasma chamber 10 would be to utilize the motive mechanism to move a shield (not shown) over the RF absorber in order to control the absorption being performed by the RF absorber, thereby changing the effects the RF absorber has on the presence of harmonic resonances in the plasma region 14 and the plasma chamber 10. The shield is made of a material that is reflective of RF frequencies, rather than being an RF absorber.

In an alternate embodiment, the motive mechanism 90 is coupled to the focus ring assembly 80.

The plasma processing system described above can be utilized in a method for mitigating chamber resonances in a plasma chamber. The method includes the steps of providing an RF absorber within the chamber enclosing a plasma region, and sealing the RF absorber from the plasma region using a protective layer on the RF absorber. Then a plasma is created by delivering RF power from an RF power source coupled to an electrode provided within the chamber to the plasma region where the RF power forms an RF electromagnetic field that interacts with a gas in the plasma region.

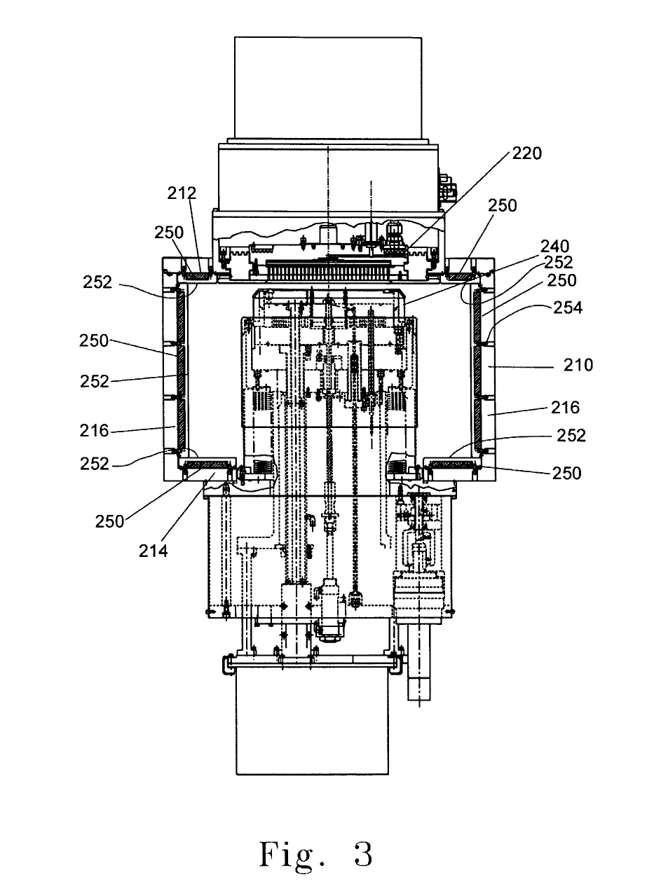

FIG. 3 is a partial cross-section view of a plasma processing system according to a third embodiment of the present invention. The plasma processing system generally includes a process chamber 210 having an upper electrode assembly 220 and a chuck assembly 240. The process chamber 210 has an upper wall 212, a lower wall 214, and a sidewall 216 that are lined with an RF absorber 250 and an absorber cover (i.e. protective layer) 252. The RF absorber 250 and absorber cover 252 are mounted to the walls of the process chamber 210 using fasteners 254.

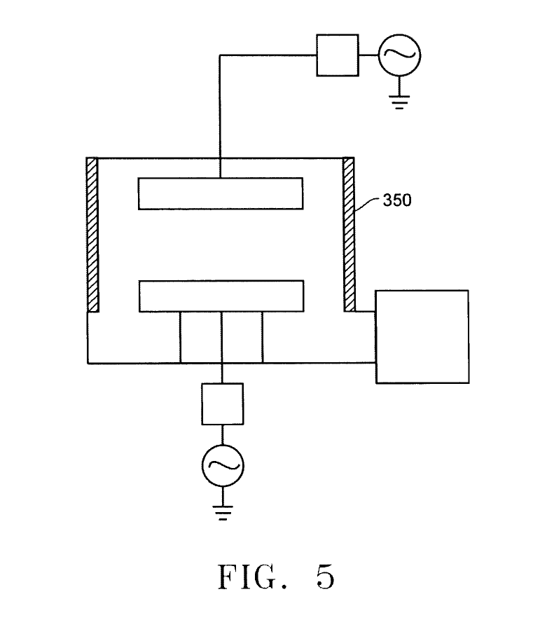

In the above description, an absorbing surface comprising an RF absorber is described according to several embodiments of the present invention. In an alternate embodiment, the absorbing surface is replaced by a non-reflecting surface. In FIG. 5, a dielectric liner 350 is installed within the chamber to provide a non-reflecting surface. The non-reflecting surface is provided within the plasma region, the non-reflecting surface comprises a layer of dielectric material and acts to minimize reflection of RF power at a design frequency. The non-reflecting surface further comprises a thickness equivalent to the quarter wavelength of a wave propagating in the dielectric layer at the design frequency. For example, in order to address the reflection of an RF electromagnetic wave at 600 MHz, the dielectric liner can be fabricated from alumina and the thickness of the dielectric liner can be chosen to be a quarter wavelength in alumina at 600 MHz, which becomes:

$$\frac{λ}{4 \sqrt{k}} = \frac{c}{4 f \sqrt{k}} = 0.0395 m = 3.95 cm ,$$

where λ is the wavelength in the dielectric liner 350, k is the dielectric constant of the dielectric material forming dielectric liner 350, c is the speed of light in a vacuum and f is the design frequency. In an alternate embodiment, dielectric liner 350 can have a variable thickness.

It should be noted that the exemplary embodiments depicted and described herein set forth the preferred embodiments of the present invention, and are not meant to limit the scope of the claims hereto in any way.

Numerous modifications and variations of the present invention are possible in light of the above teachings. It is therefore to be understood that, within the scope of the appended claims, the invention may be practiced otherwise than as specifically described herein.

1. A plasma processing system comprising:
chamber enclosing a plasma region;
RF plasma source including an RF power source coupled to an electrode provided within said chamber to deliver RF power into said plasma region where the RF power forms an RF electromagnetic field that interacts with a gas in said plasma region to create a plasma;
at least one absorbing surface comprising an RF absorber provided within said plasma region; and
protective layer provided on said RF absorber to seal said RF absorber from said plasma region.

2. The plasma processing system according to claim 1, wherein said RF absorber is encased within said protective layer.

3. The plasma processing system according to claim 1, wherein said protective layer couples said RF absorber to an interior surface of said chamber.

4. The plasma processing system according to claim 1, wherein said protective layer is made of ceramic.

5. The plasma processing system according to claim 1, wherein said protective layer is made of quartz.

6. The plasma processing system according to claim 1, wherein said protective layer is a one-piece chamber liner that is coupled to an interior surface of said chamber, said RF absorber being located between said protective layer and said interior surface of said chamber.

7. The plasma processing system according to claim 1, further comprising a cooling system coupled to said RF absorber and configured to extract heat from said RF absorber.

8. The plasma processing system according to claim 7, further comprising a permanent magnet provided in conjunction with said RF absorber.

9. The plasma processing system according to claim 1, wherein said RF absorber has a portion that extends around said plasma region.

10. The plasma processing system according to claim 1, wherein said RF absorber has a ring-shaped configuration extending downward from an injection assembly of said plasma chamber and around a chuck assembly of said plasma chamber.

11. The plasma processing system according to claim 1, further comprising a motive mechanism coupled to and configured to adjust a position of said RF absorber within said chamber.

12. The plasma processing system according to claim 1, wherein said RF absorber is provided within a focus ring assembly.

13. A plasma processing system comprising:
chamber enclosing a plasma region;
RF plasma source including an RF power source coupled to an electrode provided within said chamber to deliver RF power into said plasma region where the RF power forms an RF electromagnetic field that interacts with a gas in said plasma region to create a plasma;
means for mitigating chamber resonances within said plasma region; and
means for sealing said means for mitigating chamber resonances from plasma within said plasma region.

14. The plasma processing system according to claim 13, wherein said means for mitigating chamber resonances is encased within said means for sealing.

15. The plasma processing system according to claim 13, wherein said means for sealing couples said means for mitigating chamber resonances to an interior surface of said chamber.

16. The plasma processing system according to claim 13, wherein said means for sealing is made of ceramic.

17. The plasma processing system according to claim 13, wherein said means for sealing is made of quartz.

18. The plasma processing system according to claim 13, wherein said means for sealing is a one-piece chamber liner that is sealed to an interior surface of said chamber, said means for mitigating chamber resonances being located between said means for sealing and said interior surface of said chamber.

19. The plasma processing system according to claim 13, further comprising means for cooling said means for mitigating chamber resonances.

20. The plasma processing system according to claim 19, further comprising at least one permanent magnet provided in conjunction with said means for mitigating chamber resonances.

21. The plasma processing system according to claim 13, wherein said means for mitigating chamber resonances has a portion that extends around said plasma region.

22. The plasma processing system according to claim 13, wherein said RF absorber has a ring-shaped configuration extending downward from an injection assembly of said plasma chamber and around a chuck assembly of said plasma chamber.

23. The plasma processing system according to claim 13, further comprising means for adjusting a configuration of said means for mitigating chamber resonances to change a level of reduction in harmonics of the RF power within said plasma region.

24. The plasma processing system according to claim 23, wherein said means for adjusting comprises a motive mechanism coupled to and configured to adjust a position of said means for mitigating chamber resonances within said chamber.

25. The plasma processing system according to claim 13, wherein said means for mitigating chamber resonances is provided within a focus ring assembly.

26. A method for mitigating chamber resonances in a plasma chamber, said method comprising the steps of:
providing an RF absorber within the chamber enclosing a plasma region;
sealing the RF absorber from the plasma region using a protective layer on the RF absorber; and
creating plasma by delivering RF power from an RF power source coupled to an electrode provided within the chamber to the plasma region where the RF power forms an RF electromagnetic field that interacts with a gas in said plasma region.

27. The method according to claim 26, further comprising a step of controlling an etch rate within the plasma region by adjusting an absorption rate of the RF absorber.

28. The method according to claim 27, wherein the step of controlling an etch rate includes adjusting a position of the RF absorber with respect to the plasma within the plasma region.

29. The method according to claim 26, further comprising a step of controlling an etch stop within the plasma region by increasing the absorption rate of the RF absorber.

30. The method according to claim 26, further comprising a step of cooling the RF absorber during the step of creating plasma.

31. The method according to claim 30, further comprising a step of providing a permanent magnet in conjunction with the RF absorber.

32. The method according to claim 26, wherein the RF absorber has a portion that extends around the plasma region.

33. The method according to claim 26, wherein the RF absorber has a ring-shaped configuration extending downward from an injection assembly of the plasma chamber and around a chuck assembly of the plasma chamber.

34. The method according to claim 26, further comprising a step of adjusting a configuration of the RF absorber to change a level of chamber reflection of the RF power within the plasma region.

35. The method according to claim 26, wherein the RF absorber is provided within a focus ring assembly.

36. A plasma processing system comprising:
a chamber enclosing a plasma region;
an RF plasma source including an RF power source coupled to an electrode provided within said chamber to deliver RF power into said plasma region where the RF power forms an RF electromagnetic field that interacts with a gas in said plasma region to create a plasma; and
at least one non-reflecting surface comprising a dielectric liner within said plasma region, wherein said dielectric liner comprises a thickness corresponding to a design frequency.

37. The plasma processing system according to claim 36, wherein said thickness of said dielectric liner corresponds to a quarter wavelength of a RF electromagnetic wave propagating in said dielectric liner at said design frequency.
